(19) United States
(12) Patent Application Publication
(10) Pub. No.: US 2025/0386739 A1
(43) Pub. Date: Dec. 18, 2025

(54) MAGNETORESISTIVE RANDOM ACCESS MEMORY DEVICE AND MANUFACTURING METHOD THEREOF

(71) Applicant: UNITED MICROELECTRONICS CORP., Hsin-Chu City (TW)

(72) Inventor: Hui-Lin Wang, Taipei City (TW)

(73) Assignee: UNITED MICROELECTRONICS CORP., Hsin-Chu City (TW)

(21) Appl. No.: 18/747,353

(22) Filed: Jun. 18, 2024

(30) Foreign Application Priority Data
May 14, 2024 (TW) 113117668

(51) Int. Cl. H10N 50/85; H10B 61/00; H10N 50/01; H10N 50/10

(52) U.S. Cl. CPC H10N 50/85; H10B 61/22; H10N 50/01; H10N 50/10

(57) ABSTRACT

A magnetoresistive random access memory (MRAM) device includes a magnetic tunneling junction (MTJ) structure, a spin-orbit torque (SOT) layer, a first cap layer, an oxide layer, a second cap layer, and a connection structure. The MTJ structure and the SOT layer are disposed above a substrate, and the MTJ structure is located on the SOT layer. The first cap layer is disposed adjacent to the MTJ structure, the oxide layer is disposed on the first cap layer, and the second cap layer is disposed on the oxide layer. The first cap layer, the oxide layer, and the second cap layer are partly disposed above the MTJ structure in a vertical direction. The connection structure is disposed above the MTJ structure and penetrates through the second cap layer, the oxide layer, and the first cap layer vertically.

### BACKGROUND OF THE INVENTION

### 1. Field of the Invention

The present invention relates to a memory device and a manufacturing method thereof, and more particularly, to a magnetoresistive random access memory device and a manufacturing method thereof.

### 2. Description of the Prior Art

There are essentially two types of data memory devices used in electronic products, non-volatile and volatile memory devices. Magnetic random access memory is a kind of non-volatile memory technology. Unlike current industry-standard memory devices, the magnetic random access memory uses magnetism instead of electrical charges to store data. In general, magnetic random access memory cells include a data layer and a reference layer. The data layer is composed of a magnetic material and the magnetization of the data layer can be switched between two opposing states by an applied magnetic field for storing binary information. The reference layer can be composed of a magnetic material in which the magnetization is pinned so that the strength of the magnetic field applied to the data layer and partially penetrating the reference layer is insufficient for switching the magnetization in the reference layer. During the read operation, the resistance of the magnetic random access memory cell is different when the magnetization alignments of the data layer and the reference layer are the same or not, and the magnetization polarity of the data layer can be identified accordingly. The structure of magnetic random access memory devices will vary depending on the technology used to magnetize the data layer. Currently, spin-transfer torque (STT) magnetic random access memory and spin-orbit torque (SOT) magnetic random access memory are relatively common technology. In addition, the manufacturing process of the magnetic random access memory may be integrated with the back end of line (BEOL) process of the semiconductor manufacturing process, and the integration with the BEOL process is influenced by the design variations of the magnetic random access memory. Therefore, how to improve the manufacturing process integration of the magnetic random access memory device through structures and/or process design is an ongoing research direction for people in related fields.

### SUMMARY OF THE INVENTION

A magnetoresistive random access memory (MRAM) device and a manufacturing method thereof are provided in the present invention. A connection structure located corresponding to a magnetic tunneling junction (MTJ) structure penetrates through a second cap layer, an oxide layer, and a first cap layer vertically for improving the manufacturing process integration of the MRAM device.

According to an embodiment of the present invention, a magnetoresistive random access memory (MRAM) device is provided. The MRAM device includes a magnetic tunneling junction (MTJ) structure, a spin-orbit torque (SOT) layer, a first cap layer, an oxide layer, a second cap layer, and a connection structure. The MTJ structure and the SOT layer are disposed above a substrate, and the MTJ structure is located on the SOT layer. The first cap layer is disposed adjacent to the MTJ structure, the oxide layer is disposed on the first cap layer, and the second cap layer is disposed on the oxide layer. The first cap layer, the oxide layer, and the second cap layer are partly disposed above the MTJ structure in a vertical direction. The connection structure is disposed above the MTJ structure and penetrates through the second cap layer, the oxide layer, and the first cap layer vertically.

According to another embodiment of the present invention, a manufacturing method of a magnetoresistive random access memory (MRAM) device is provided. The manufacturing method includes the following steps. A magnetic tunneling junction (MTJ) structure is formed above a substrate. A spin-orbit torque (SOT) layer is formed above the substrate, and the MTJ structure is located on the SOT layer. A first cap layer is formed adjacent to the MTJ structure, an oxide layer is formed on the first cap layer, and a second cap layer is formed on the oxide layer. The first cap layer, the oxide layer, and the second cap layer are partly located above the MTJ structure in a vertical direction. A connection structure is formed above the MTJ structure, and the connection structure penetrates through the second cap layer, the oxide layer, and the first cap layer vertically.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a magnetoresistive random access memory device according to an embodiment of the present invention.

FIGS. 2-11 are schematic drawings illustrating a manufacturing method of a magnetoresistive random access memory device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, and FIG. 11 is a schematic drawing in a step subsequent to FIG. 10.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

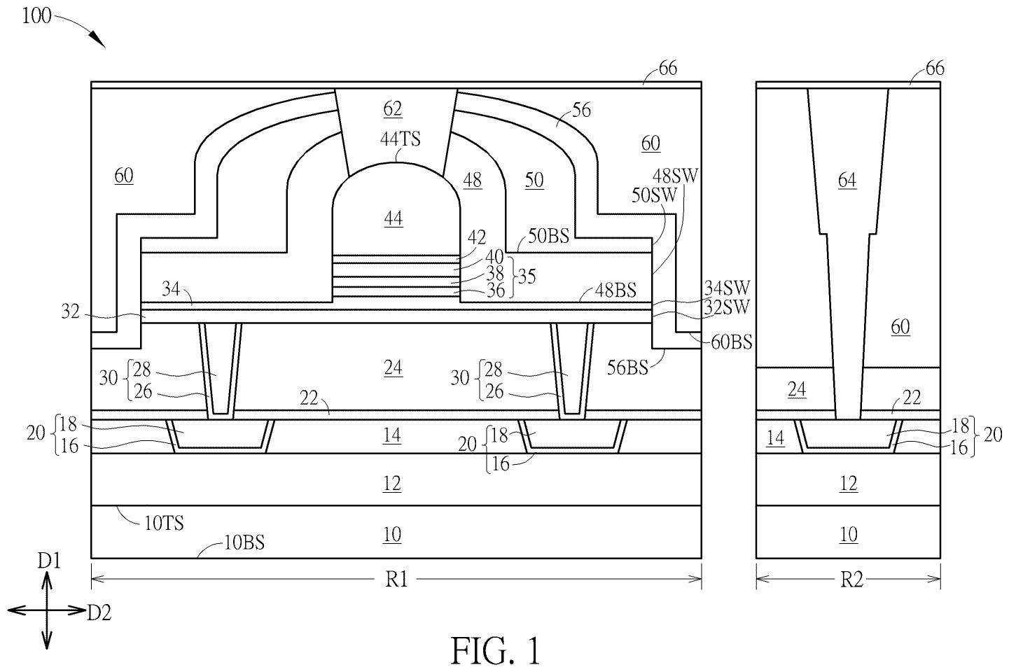

Please refer to FIG. 1. FIG. 1 is a schematic drawing illustrating a magnetoresistive random access memory (MRAM) device 100 according to an embodiment of the present invention. As shown in FIG. 1, the MRAM device 100 includes a magnetic tunneling junction (MTJ) structure (such as a MTJ structure 35), a spin-orbit torque (SOT) layer (such as a SOT layer 34), a first cap layer 48, an oxide layer 50, a second cap layer 56, and a connection structure 62. The MTJ structure 35 and the SOT layer 34 are disposed above a substrate 10, and the MTJ structure 35 is located on the SOT layer 34. The first cap layer 48 is disposed adjacent to the MTJ structure 35, the oxide layer 50 is disposed on the first cap layer 48, and the second cap layer 56 is disposed on the oxide layer 50. The first cap layer 48, the oxide layer 50, and the second cap layer 56 are partly disposed above the MTJ structure 35 in a vertical direction D1. The connection structure 62 is disposed above the MTJ structure 35 and penetrates through the second cap layer 56, the oxide layer 50, and the first cap layer 48 vertically. The first cap layer 48, the oxide layer 50, and the second cap layer 56 are formed above the MTJ structure 35, and the connection structure 62 penetrates through the second cap layer 56, the oxide layer 50, and the first cap layer 48 vertically for improving manufacturing process integration between the connection structure 62 and structures on other regions. The related manufacturing yield may be enhanced accordingly.

In some embodiments, the vertical direction D1 may be regarded as a thickness direction of the substrate 10. The substrate 10 may have a top surface 10TS and a bottom surface 10BS opposite to the top surface 10TS in the vertical direction D1, and the MTJ structures 35, the SOT layer 34, the first cap layer 48, the oxide layer 50, the second cap layer 56, and the connection structure 62 described above may be disposed at the side of the top surface 10TS. A horizontal direction substantially orthogonal to the vertical direction D1 (such as a horizontal direction D2) may be substantially parallel with the top surface 10TS and/or the bottom surface 10BS of the substrate 10, but not limited thereto. In this description, a distance between the bottom surface 10BS of the substrate 10 and a relatively higher location and/or a relatively higher part in the vertical direction D1 may be greater than a distance between the bottom surface 10BS of the substrate 10 and a relatively lower location and/or a relatively lower part in the vertical direction D1. The bottom or a lower portion of each component may be closer to the bottom surface 10BS of the substrate 10 in the vertical direction D1 than the top or upper portion of this component. Another component disposed above a specific component may be regarded as being relatively far from the bottom surface 10BS of the substrate 10 in the vertical direction D1, and another component disposed under a specific component may be regarded as being relatively close to the bottom surface 10BS of the substrate 10 in the vertical direction D1. It is worth noting that, in this description, a top surface of a specific component may include the topmost surface of this component in the vertical direction D1, and a bottom surface of a specific component may include the bottommost surface of this component in the vertical direction D1, but not limited thereto. Additionally, in this description, the condition that a certain component is disposed between two other components in a specific direction may include but is not limited to a condition that the certain component is sandwiched between the two other components in the specific direction.

In some embodiments, the substrate 10 may include a memory region R1 and a logic region R2. The MTJ structure 35, the SOT layer 34, and the connection structure 62 described above may be disposed above the memory region R1, and the memory region R1 may be regarded as a MRAM cell region, but not limited thereto. In some embodiments, the MRAM device 100 may further include a bottom electrode 32, a cap layer 42, and a top electrode 44. The bottom electrode 32 may be disposed between the SOT layer 34 and the substrate 10 in the vertical direction D1, the top electrode 44 is disposed on the MTJ structure 35 in the vertical direction D1, and the cap layer 42 may be disposed between the top electrode 44 and the MTJ structure 35 in the vertical direction D1. The first cap layer 48, the oxide layer 50, and the second cap layer 56 may be partly located above the top electrode 44 in the vertical direction D1, and the connection structure 62 may penetrate through the second cap layer 56, the oxide layer 50, and the first cap layer 48 vertically for contacting and being electrically connected with the top electrode 44.

In some embodiments, the MRAM device 100 may further include a dielectric layer 12, a dielectric layer 14, a plurality of connection structures 20, a stop layer 22, a dielectric layer 24, and a plurality of connection structures 30. The dielectric layer 14 and the dielectric layer 14 may be disposed above the memory region R1 and the logic region R2, the dielectric layer 14 is disposed on the dielectric layer 12, and the connection structures 20 are disposed in the dielectric layer 14. The stop layer 22 may cover the connection structures 20 and the dielectric layer 14 located on the memory region R1 and the logic region R2, and the dielectric layer 24 is disposed on the stop layer 22 and located on the memory region R1 and the logic region R2. The connection structures 30 may be disposed in the dielectric layer 24 and the stop layer 22 located on the memory region R1, and the bottom electrode 32 may be disposed on the dielectric layer 24 and electrically connected with two of the connection structures 30, but not limited thereto. In some embodiments, the connection structure 20 and the connection structure 30 may be regarded as a trench conductor and a via conductor, respectively, but not limited thereto.

In some embodiments, the substrate 10 may include a semiconductor substrate or a non-semiconductor substrate. The semiconductor substrate may include a silicon substrate, a silicon germanium semiconductor substrate or a silicon-on-insulator (SOI) substrate, and the non-semiconductor substrate may include a glass substrate, a plastic substrate, or a ceramic substrate, but not limited thereto. For example, when the substrate 10 includes a semiconductor substrate, a plurality of field effect transistors (not shown), a dielectric layer covering the field effect transistors (such as the dielectric layer 12 and the dielectric layer 14), and the connection structures 20 electrically connected with the field effect transistors may be disposed on the semiconductor substrate according to some considerations, and the connection structure 30 electrically connected with the bottom electrode 32 may be electrically connected with specific transistor via the corresponding connection structure 20, but not limited thereto. In some embodiments, electrical current may be formed in the bottom electrode 32 via the two connection structures 30 connected with the bottom electrode 32, and the magnetic moment and the magnetization effect influencing the MTJ structure 35 may be formed by the electrical current passing through the SOT layer 34. In addition, the MTJ structures 35 may include a free layer 36, a barrier layer 38, and a reference layer 40 stacked sequentially from bottom to top, but not limited thereto. The top electrode 44 may be directly above the MTJ structure 35 and the cap layer 42 in the vertical direction D1, and a top surface 44TS of the top electrode 44 may include a curved surface because of the influence of the manufacturing process characteristics, but not limited thereto. In some embodiments, the first cap layer 48 may cover and contact a top surface of the SOT layer 34, a sidewall of the MTJ structure 35, and a surface of the top electrode 44, and a bottom surface of the first cap layer 48 (such as a bottom surface 48BS of the first cap layer 48 located on the SOT layer 34 in the vertical direction D1 and directly contacting the SOT layer 34) may be lower than the top surface 44TS of the top electrode 44 in the vertical direction D1, but not limited thereto. In some embodiments, a protection layer (not illustrated) may be disposed between the sidewall of the MTJ structure 35 and the first cap layer 48, and the protection layer may be formed in the process of forming the MTJ structure 35 concurrently, but not limited thereto.

In some embodiments, because of the influence of related processes, a top surface of the SOT layer 34 without being covered by the MTJ structure 35 in the vertical direction D1 may be slightly lower than a top surface of the SOT layer 34 located under the MTJ structure 35 in the vertical direction D1, but not limited thereto. Additionally, because of the influence of the top surface 44TS of the top electrode 44, the top surfaces of the first cap layer 48, the oxide layer 50, and the second cap layer 56 may include curved surfaces also. The oxide layer 50 may directly contact the first cap layer 48, and a sidewall 50SW of the oxide layer 50, a sidewall 48SW of the first cap layer 48, a sidewall 34SW of the SOT layer 34, and a sidewall 32SW of the bottom electrode 32 may be substantially aligned with one another (such as being aligned with one another in the horizontal direction D2) and/or flush with one another, but not limited thereto. In addition, because of the influence of related processes, a top surface of the dielectric layer 24 without being covered by the bottom electrode 32 in the vertical direction D1 may be lower than a top surface of the dielectric layer 24 located under the bottom electrode 32 in the vertical direction D1, and the second cap layer 56 may be disposed conformally on and directly contact the top surface and the sidewall 50SW of the oxide layer 50, the sidewall 48SW of the first cap layer 48, the sidewall 34SW of the SOT layer 34, the sidewall 32SW of the bottom electrode 32, and the dielectric layer 24. Therefore, a bottom surface of the second cap layer 56 (such as a bottom surface 56BS of the second cap layer 56 located on the dielectric layer 24 in the vertical direction D1 and directly contacting the dielectric layer 24) may be lower than the bottom surface 48BS of the first cap layer 48 in the vertical direction D1. The bottom surface 48BS of the first cap layer 48, a bottom surface 50BS of the oxide layer 50, and the bottom surface 56BS of the second cap layer 56 may be lower than the top surface 44TS of the top electrode 44 in the vertical direction D1.

In some embodiments, a material composition of the oxide layer 50 may be different from a material composition of the first cap layer 48 and a material composition of the second cap layer 56, and the material composition of the first cap layer 48 may be identical to the material composition of the second cap layer 56, but not limited thereto. For example, the oxide layer 50 may include silicon oxide, such as tetraethoxysilane (TEOS) or other suitable oxide dielectric materials, and the first cap layer 48 and the second cap layer 56 may include silicon nitride or other suitable cap materials. In addition, the oxide layer 50 located above the MTJ structure 35 is sandwiched between the first cap layer 48 and the second cap layer 56 in the vertical direction D1, and the top surface of the first cap layer 48, the top surface of the oxide layer 50, and a top surface of the second cap layer 56 may be higher than the top surface 44TS of the top electrode 44 in the vertical direction D1 accordingly. In addition, the first cap layer 48, the oxide layer 50, and the second cap layer 56 may surround the sidewall of the MTJ structure 35, the sidewall of the cap layer 42, and the sidewall of the top electrode 44 in the horizontal direction (such as the horizontal direction D2, but not limited thereto), and a part of the oxide layer 50 may be sandwiched between the first cap layer 48 and the second cap layer 56 in the horizontal direction. In some embodiments, the MRAM device 100 may further include an interlayer dielectric layer 60, an interconnection structure 64, and a stop layer 66. The interlayer dielectric layer 60 is disposed above the memory region R1 and the logic region R2. The interlayer dielectric layer 60 located above the memory region R1 may be disposed on the second cap layer 56, and the interlayer dielectric layer 60 located above the logic region R2 may be disposed on and directly contacting the dielectric layer 24. In some embodiments, because of the influence of the related processes, the top surface of the dielectric layer 24 located above the logic region R2 may be lower than the top surface of the dielectric layer 24 located above the memory region R1. The thickness of the interlayer dielectric layer 60 located above the logic region R2 may be greater than the thickness of the interlayer dielectric layer 60 located above the memory region R1, and the top surface of the interlayer dielectric layer 60 located above the memory region R1 and the top surface of the interlayer dielectric layer 60 located above the logic region R2 may be substantially coplanar. The interconnection structure 64 may include a dual damascene structure or other suitable structures, and the interconnection structure 64 may be disposed above the logic region R2 and penetrate through the interlayer dielectric layer 60, the dielectric layer 24, and the stop layer 22 in the vertical direction D1 for contacting and being electrically connected with the connection structure 20 located corresponding to the interconnection structure 64. In some embodiments, the top surface of the connection structure 62, the top surface of the interconnection structure 64, and the top surface of the interlayer dielectric layer 60 may be substantially coplanar, and the stop layer 66 may be disposed on and contact the top surfaces of the connection structure 62, the interconnection structure 64, and the interlayer dielectric layer 60.

In some embodiments, the dielectric layer 12, the dielectric layer 14, and the dielectric layer 24 may include an oxide dielectric material, a low dielectric constant dielectric material (such as a dielectric material with dielectric constant lower than 2.9, but not limited thereto), or other suitable dielectric materials. The interlayer dielectric layer 60 may include a low dielectric constant dielectric material or an ultra-low dielectric constant (ULK) dielectric material (such as a dielectric material with dielectric constant lower than 2.7, but not limited thereto), and a dielectric constant of the interlayer dielectric layer 60 may be lower than a dielectric constant of the oxide layer 50, but not limited thereto. In some embodiments, the connection structure 20, the connection structure 30, the connection structure 62, and the interconnection structure 64 may respectively include a barrier layer and an electrically conductive material disposed on the barrier layer. The barrier layer may include titanium (Ti), titanium nitride, tantalum (Ta), tantalum nitride, or other suitable electrically conductive battier materials, and the electrically conductive material may include tungsten (W), copper (Cu), aluminum (Al), titanium aluminide, cobalt tungsten phosphide, or other suitable electrically conductive materials with relatively low electrical resistivity. For example, the connection structure 20 may include a barrier layer 16 and an electrically conductive material 18 disposed on the barrier layer 16, and the connection structure 30 may include a barrier layer 26 and an electrically conductive material 28 disposed on the barrier layer 26, but not limited thereto. The stop layer 22 and the stop layer 66 may include nitrogen doped carbide (NDC), silicon nitride, silicon carbon nitride (SiCN), or other suitable materials. The bottom electrode 32 may include tantalum, tantalum nitride, platinum (Pt), copper, gold (Au), aluminum, or other suitable electrically conductive materials. The top electrode 44 may include tantalum, tantalum nitride, titanium, titanium nitride, platinum, copper, gold, aluminum, or other suitable electrically conductive materials. The cap layer 42 may include ruthenium (Ru), or other suitable electrically conductive materials.

The SOT layer 34 may include a SOT material, and the SOT material may be defined as a material capable of generating the spin Hall effect and/or a material with greater spin-orbit coupling strength, so as to generate spin-orbit torque on the free layer 36 and change the direction of the magnetic torque of the free layer 36. For example, the SOT material may include hafnium (Hf), rhenium (Re), ruthenium, gold, platinum, tantalum, tungsten, iridium (Ir), palladium (Pd), an alloy of the materials described above (such as IrPt, PtAu, PtPd, BiSb, and so forth), a compound of the materials described above (such as PrS, WTe₂, and so forth), or other suitable materials (such as BiSb and BiₓSe₁₋ₓ). The free layer 36 and the reference layer 40 may include ferromagnetic materials, such as iron, cobalt, nickel, cobalt-iron (CoFe), cobalt-iron-boron (CoFeB), or other suitable ferromagnetic materials. In some embodiments, the reference layer 40 and an antiferromagnetic layer (not illustrated) may constitute a pinned layer with fixed direction of magnetic torque. The antiferromagnetic layer may include antiferromagnetic materials, such as iron manganese (FeMn), platinum manganese (PtMn), iridium manganese (IrMn), nickel oxide (NiO), a cobalt/platinum (Co/Pt) multilayer, or other suitable antiferromagnetic materials. The barrier layer 38 may include insulation materials, such as magnesium oxide (MgO), aluminum oxide, or other suitable insulation materials.

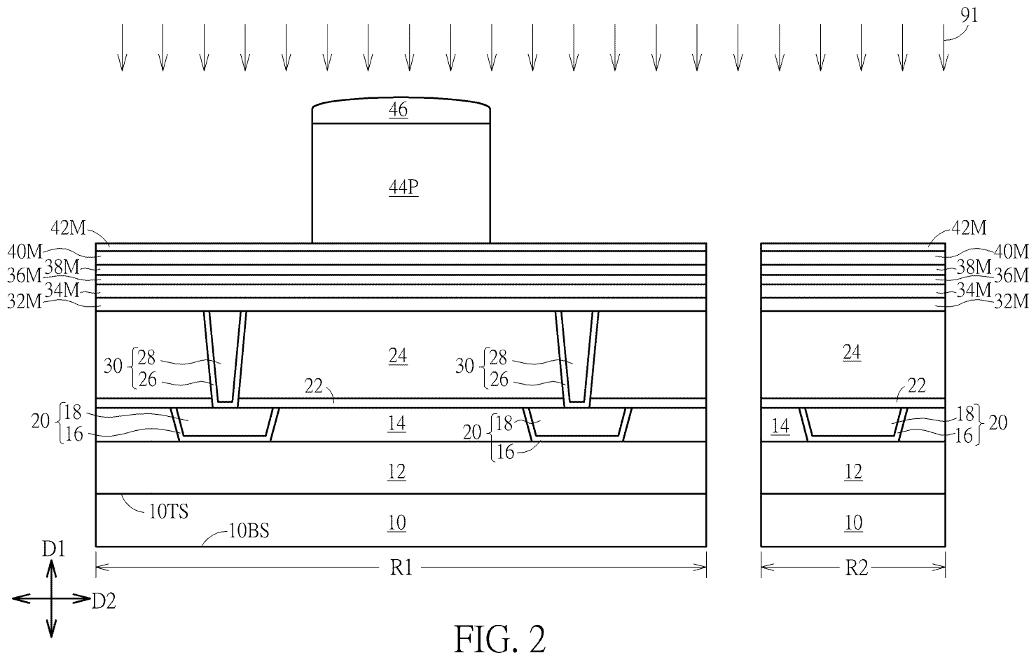

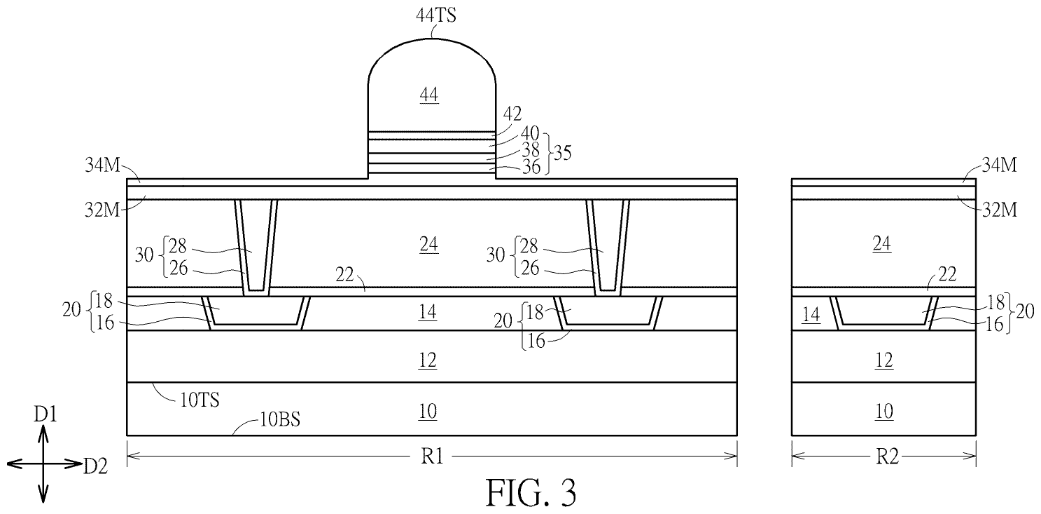

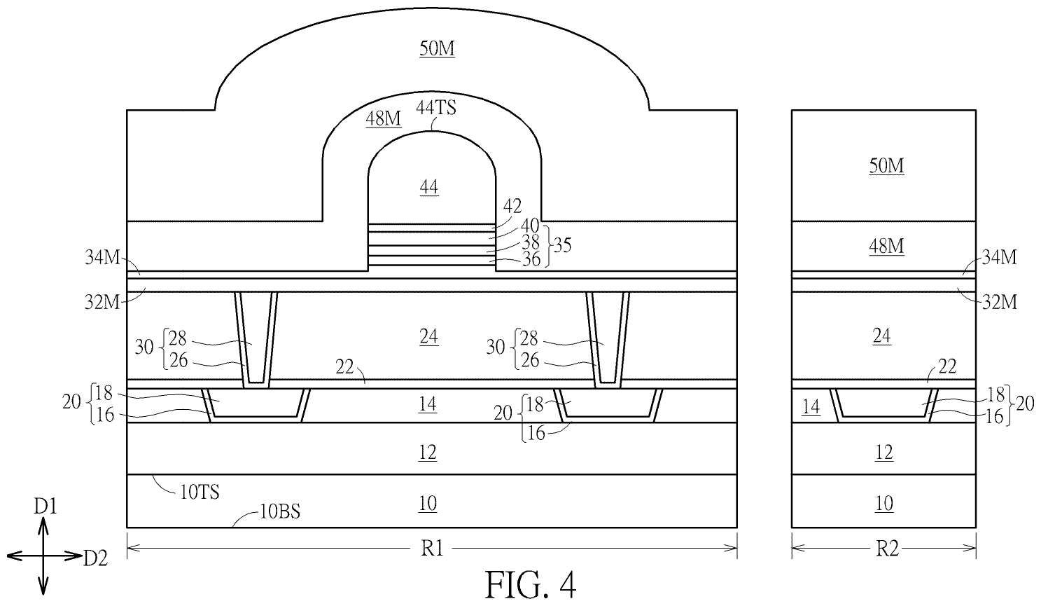

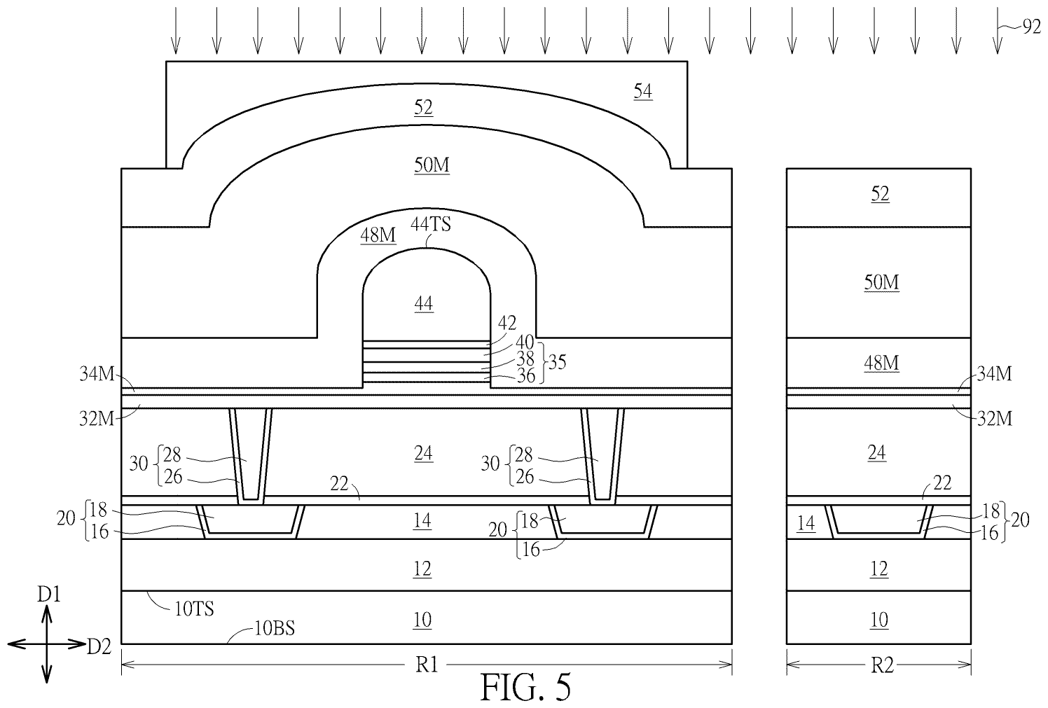

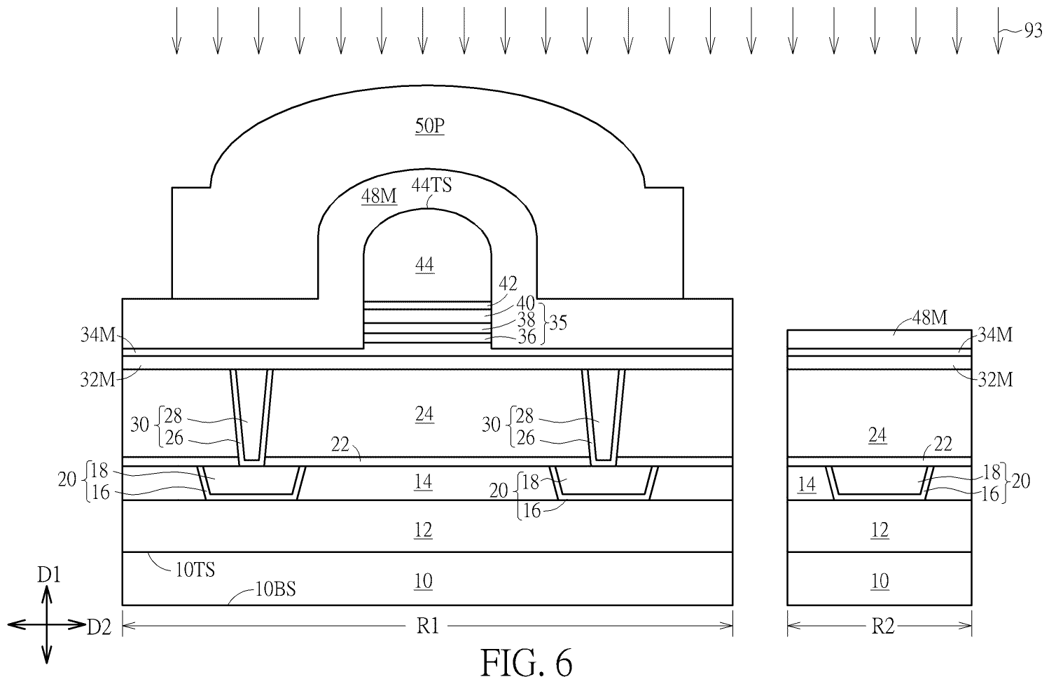

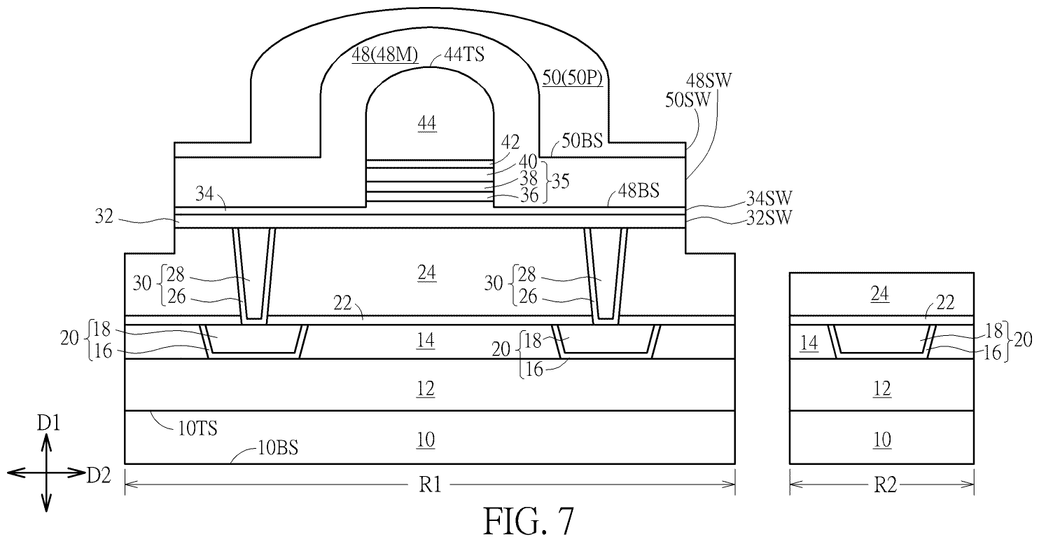

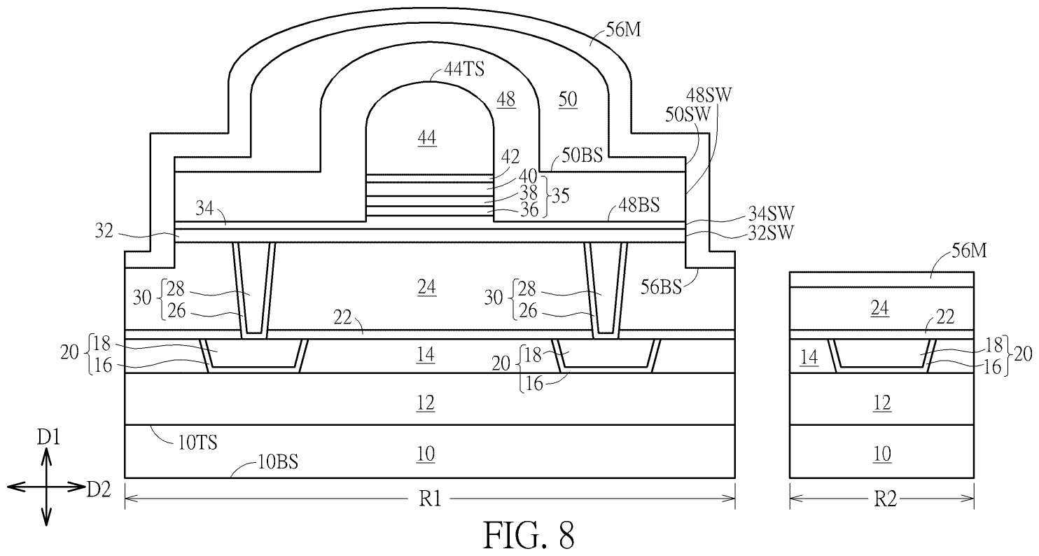

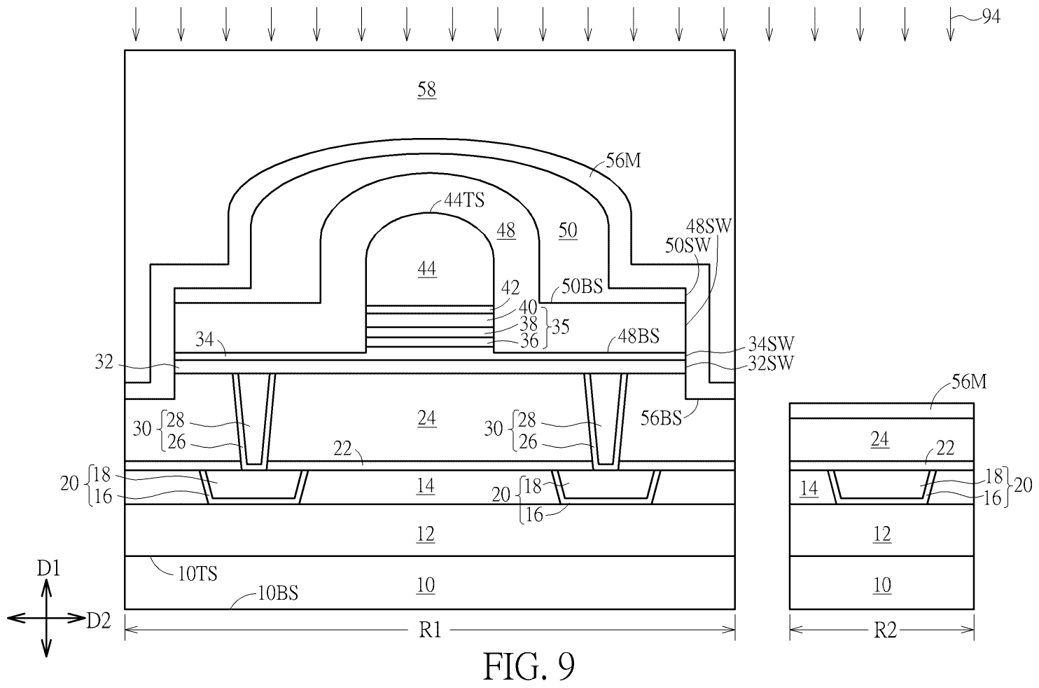

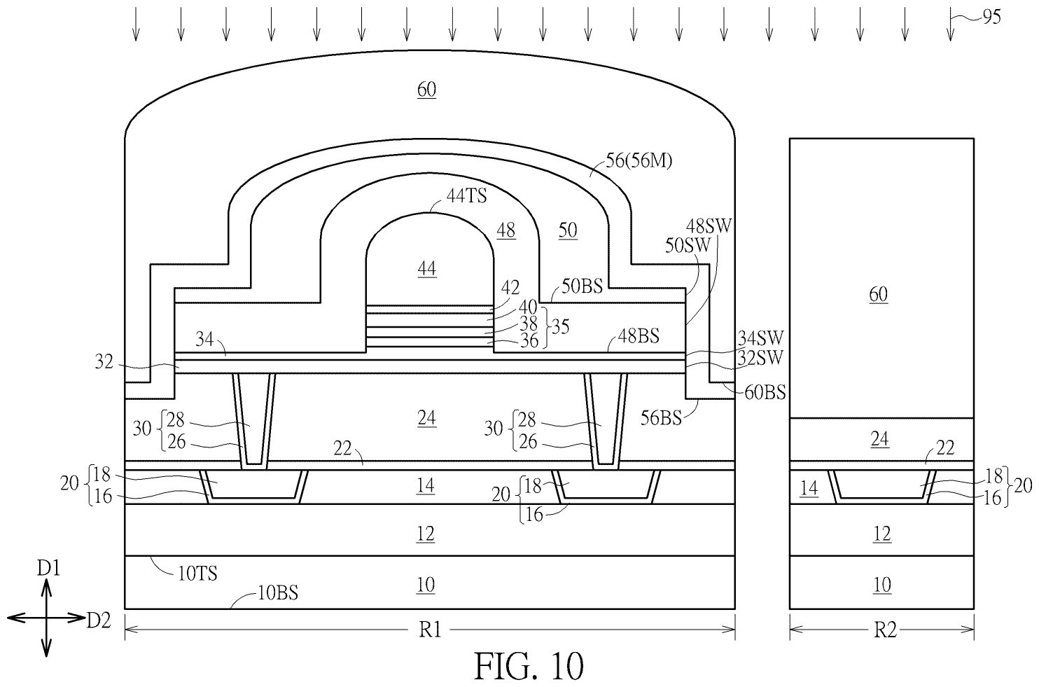

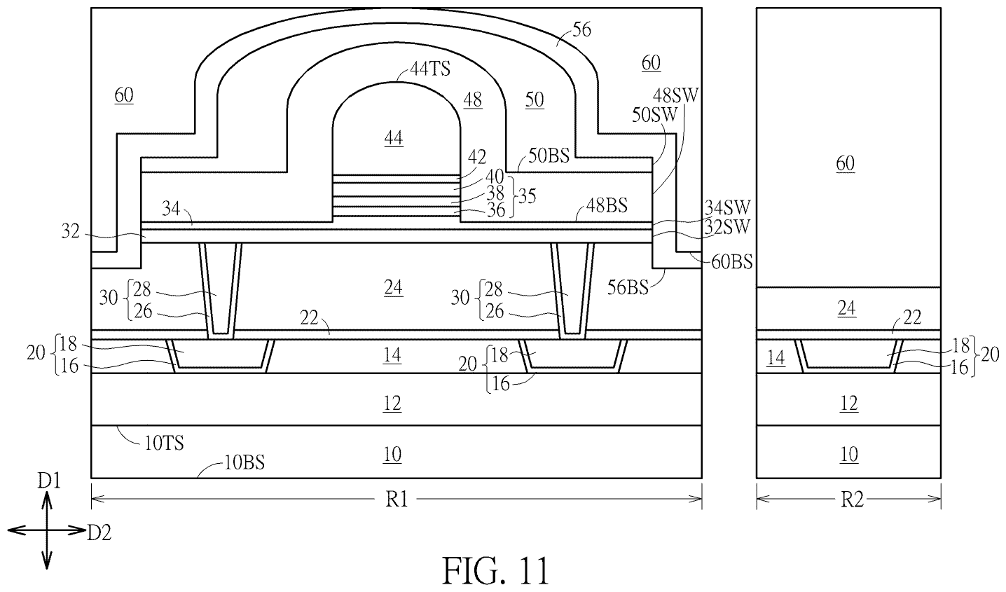

Please refer to FIGS. 1-11. FIGS. 2-11 are schematic drawings illustrating a manufacturing method of a magnetoresistive random access memory device according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, and FIG. 11 is a schematic drawing in a step subsequent to FIG. 10. In some embodiments, FIG. 1 may be regarded as a schematic drawing in a step subsequent to FIG. 11, but not limited thereto. As shown in FIG. 1, the manufacturing method in this embodiment includes the following steps. The magnetic tunneling junction (MTJ) structure (such as the MTJ structure 35) and the spin-orbit torque (SOT) layer (such as the SOT layer 34) are formed above the substrate 10, and the MTJ structure 35 is located on the SOT layer 34. The first cap layer 48 is formed adjacent to the MTJ structure 35, the oxide layer 50 is formed on the first cap layer 48, and the second cap layer 56 is formed on the oxide layer 50. The first cap layer 48, the oxide layer 50, and the second cap layer 56 are partly located above the MTJ structure 35 in the vertical direction D1. The connection structure 62 is formed above the MTJ structure 35, and the connection structure 62 penetrates through the second cap layer 56, the oxide layer 50, and the first cap layer 48 vertically.

Specifically, the manufacturing method in this embodiment may include but is not limited to the following steps. As shown in FIG. 2, active components (such as the transistors described above), passive components, or other required circuit structures may be formed on the substrate 10, and the dielectric layer 12, the dielectric layer 24, the connection structures 20, the stop layer 22, the dielectric layer 24, and the connection structures 30 described above may then be formed. Subsequently, an electrically conductive material 32M, a SOT material 34M, a ferromagnetic material 36M, a barrier material 38M, a ferromagnetic material 40M, and a cap material 42M may be sequentially formed above the memory region R1 and the logic region R2 of the substrate 10. Afterwards, a patterned electrically conductive material 44P may be formed on the cap material 42M located above the memory region R1. In some embodiments, an electrically conductive material may be formed on the cap material 42M, a mask layer 46 may be formed on this electrically conductive material, and a patterning process using a patterned mask layer (such as a patterned photoresist layer, not illustrated) as a mask (such as a reactive ion etching (RIE) process, but not limited thereto) may then be performed to the mask layer 46 and the electrically conductive material for forming the patterned electrically conductive material 44P. The mask layer 46 may be removed after this patterning process or remain on the patterned electrically conductive material 44P after this patterning process. The mask layer 46 may include an oxide mask material (such as silicon oxide) or other suitable mask materials. As shown in FIG. 2 and FIG. 3, an etching process 91 using the patterned electrically conductive material 44P and/or the mask layer 46 as a mask may then be performed for removing a part of the cap material 42M, a part of the ferromagnetic material 40M, a part of the barrier material 38M, and a part of the ferromagnetic material 36M and forming the MTJ structure 35 including the reference layer 40, the barrier layer 38, and the free layer 36 and the cap layer 42 on the SOT material 34M. In some embodiments, the etching process 91 may include an ion beam etching (IBE) process or other suitable etching approaches, and the patterned electrically conductive material 44P may be partially etched by the etching process 91 to be the top electrode 44 located above the MTJ structure 35. Additionally, in some embodiments, the top electrode 44 may have a curved top surface protruding upwards by adjusting the process parameters of the etching process 91 for enhancing the sidewall etching efficiency in the IBE process, but not limited thereto. In some embodiments, the SOT material 34M may be partly etching by the etching process 91, and a top surface of the SOT material 34M without being covered by the MTJ structure 35 in the vertical direction D1 may be slightly lower than a top surface of the SOT material 34M located under the MTJ structure 35 in the vertical direction D1, but not limited thereto.

As shown in FIGS. 2-4, after the MTJ structure 35 and the top electrode 44 are formed, a cap material 48M may be formed and an oxide material 50M may be formed on the cap material 48M. The cap material 48M and the oxide material 50M may be formed above the memory region R1 and the logic region R2. In some embodiments, after the etching process 91, a protection layer (not illustrated) may be formed by oxidizing the sidewall of the MTJ structure 35 in-situ, and the cap material 48M may be formed in-situ also after the protection layer is formed, but not limited thereto. The cap material 48M may be formed on the top electrode 44, the MTJ structure 35, and the SOT material 34M and cover the SOT material 34M, the sidewall of the MTJ structure 35, and the top electrode 44. The cap material 48M and the oxide material 50M may have curved top surfaces protruding upwards because of the influence of the top electrode 44. Subsequently, as shown in FIG. 5 and FIG. 6, an anti-reflection layer 52 (such as a bottom anti-reflection layer, but not limited thereto) and a patterned mask layer 54 (such as a patterned photoresist layer, but not limited thereto) may be formed on the oxide material 50M, and an etching process 92 (such as a RIE process, but not limited thereto) using the patterned mask layer 54 as a mask may be performed. At least a part of the oxide material 50M may be etched by the etching process 92 to be a patterned oxide material 50P formed on the cap material 48M, and the oxide material 50M located above the logic region R2 and the anti-reflection layer 52 located above the logic region R2 may be completely removed by the etching process 92. Additionally, the patterned mask layer 54 and the remaining anti-reflection layer 52 may be removed after the etching process 92. Because of the process characteristics of the etching process 92 (such as loading effect, but not limited thereto), the cap material 48M located above the logic region R2 may be partially etched by the etching process 92, and the top surface of the cap material 48M located above the logic region R2 may be lower than the top surface of the cap material 48M located above the memory region R1 after the etching process 92 accordingly, but not limited thereto.

Subsequently, as shown in FIG. 6 and FIG. 7, an etching process 93 (such as a small angle IBE process, but not limited thereto) using the patterned oxide material 50P as a mask may be performed, and a part of the patterned oxide material 50P may be located above the MTJ structure 35 and the cap material 48M in the vertical direction D1 after the etching process 93. In other words, the top surface of the cap material 48M is not exposed by the etching process 93. In addition, the cap material 48M may be etched to be the first cap layer 48 by the etching process 93, the SOT material 34M may be etched to be the SOT layer 34 by the etching process 93, the electrically conductive material 32M may be etched to be the bottom electrode 32 by the etching process 93, and the patterned oxide material 50P may be partially etched to be the oxide layer 50 by the etching process 93. In some embodiments, the electrically conductive material 32M, the SOT material 34M, and the cap material 48M may be partly formed above the memory region R1 and partly formed above the logic region R2. The cap material 48M, the SOT material 34M, and the electrically conductive material 32M located above the logic region R2 may be completely removed by the etching process 93, but not limited thereto. Additionally, in some embodiments, the dielectric layer 24 may be partially etched by the etching process 93, and because of the influence of the process characteristics of the etching process 93 and/or the difference in the material layers on the dielectric layer 24, the top surface of the dielectric layer 24 located above the logic region R2 may be lower than the top surface of the dielectric layer 24 located above the memory region R1 after the etching process 93, and the top surface of the dielectric layer 24 located above the memory region R1 without being covered by the bottom electrode 32 may be lower than the top surface of the dielectric layer 24 under the bottom electrode 32 in the vertical direction D1. In addition, the oxide layer 50, the first cap layer 48, the SOT layer 34, and the bottom electrode 32 may be formed concurrently by the etching process 93, and the sidewall 50SW of the oxide layer 50, the sidewall 48SW of the first cap layer 48, the sidewall 34SW of the SOT layer 34, and the sidewall 32SW of the bottom electrode 32 may be substantially aligned with one another (such as being aligned with one another in the horizontal direction D2) and/or flush with one another accordingly, but not limited. It is worth noting that the method of forming the SOT layer 34 in this invention may include but is not limited to the steps shown in FIGS. 2-7 described above, and the SOT layer 34 illustrated in the FIG. 7 and FIG. 1 may also be formed by other suitable approaches according to some design considerations.

Subsequently, as shown in FIGS. 6-8, after the etching process 93, a cap material 56M may be formed above the memory region R1 and the logic region R2. The cap material 56M located above the logic region R2 may be formed on the dielectric layer 24, and the cap material 56M located above the memory region R1 may cover the top surface and the sidewall 50SW of the oxide layer 50, the sidewall 48SW of the first cap layer 48, the sidewall 34SW of the SOT layer 34, the sidewall 32SW of the bottom electrode 32, and a part of the dielectric layer 24. In some embodiments, the cap material 56M may be formed in-situ after the etching process 93, but not limited thereto. Subsequently, as shown in FIG. 9 and FIG. 10, a patterned mask layer 58 (such as a patterned photoresist layer, but not limited thereto) may be formed on the cap material 56M located above the memory region R1, and an etching process 94 using the patterned mask layer 58 as a mask may be performed for removing a part of the cap material 56M (such as the cap material 56M located above the logic region R2) and forming the second cap layer 56. At least a part of the cap material 56M located above the memory region R1 may be etched to be the second cap layer 56 by the etching process 94, and the patterned mask layer 58 may be removed after the etching process 94. As shown in FIG. 10 and FIG. 11, after the step of forming the second cap layer 56, an interlayer dielectric layer 60 may be formed above the memory region R1 and the logic region R2. The interlayer dielectric layer 60 located above the logic region R2 may be formed on the dielectric layer 24, and the interlayer dielectric layer 60 located above the memory region R2 may be formed on the second cap layer 56. Subsequently, a planarization process 95 may be performed to the interlayer dielectric layer 60, and the planarization process 95 may include a chemical mechanical polishing (CMP) process or other suitable planarization approaches. In some embodiments, the planarization process 95 may stop on the second cap layer 56, at least a part of the top surface of the second cap layer 56 may be exposed by the planarization process 95, and a bottom surface of the interlayer dielectric layer 60 (such as a bottom surface 60BS of the interlayer dielectric layer 60 without being located above the SOT layer 34 in the vertical direction D1) may be lower than the MTJ structure 35 in the vertical direction D1, but not limited thereto.

Subsequently, as shown in FIG. 1, the connection structure 62, the interconnection structure 64, and the stop layer 66 may be formed for forming the MRAM device 100. In some embodiments, an opening corresponding to the connection structure 62 and an opening corresponding to the interconnection structure 64 may be formed, these openings may be filled with an electrically conductive material, and another planarization process may be performed to remove the electrically conductive material located outside the openings for forming the connection structure 62 and the interconnection structure 64. Therefore, the top surface of the connection structure 62, the top surface of the interconnection structure 64, and the top surface of the interlayer dielectric layer 60 may be substantially coplanar, but not limited thereto. The opening corresponding to the connection structure 62 may penetrate through the interlayer dielectric layer 60, the second cap layer 56, the oxide layer 50, and the first cap layer 48 located above the top electrode 44, and the opening corresponding to the interconnection structure 64 (such as a trench and a via hole corresponding to the dual damascene structure) may penetrate through the interlayer dielectric layer 60, the dielectric layer 24, and the stop layer 22 located above the logic region R2. By the design that the opening corresponding to the connection structure 62 has to penetrate through the second cap layer 56, the oxide layer 50, and the first cap layer 48 vertically, the negative influence of the step of forming the opening corresponding to the connection structure 62 on the top electrode 44 may be reduced, especially when the opening corresponding to the connection structure 62 and at least a part of the opening corresponding to the interconnection structure 64 are formed concurrently by the same process. The manufacturing yield may be enhanced and/or the process integration between the memory region R1 and the logic region R2 may be improved accordingly.

To summarize the above descriptions, in the MRAM device and the manufacturing method thereof according to the present invention, the oxide layer used to define the SOT layer and the second cap layer may be partly disposed above the MTJ structure, and the connection structure corresponding to the MTJ structure vertically penetrates through the second cap layer, the oxide layer, and the first cap layer for improving the process integration of the MRAM device and/or enhancing related manufacturing yield.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A magnetoresistive random access memory (MRAM) device, comprising:
a magnetic tunneling junction (MTJ) structure disposed above a substrate;
a spin-orbit torque (SOT) layer disposed above the substrate, wherein the MTJ structure is located on the SOT layer;
a first cap layer disposed adjacent to the MTJ structure;
an oxide layer disposed on the first cap layer;
a second cap layer disposed on the oxide layer, wherein the first cap layer, the oxide layer, and the second cap layer are partly disposed above the MTJ structure in a vertical direction; and
a connection structure disposed above the MTJ structure and penetrating through the second cap layer, the oxide layer, and the first cap layer vertically.

2. The MRAM device according to claim 1, further comprising:
a top electrode disposed on the MTJ structure, wherein the first cap layer, the oxide layer, and the second cap layer are partly located above the top electrode in the vertical direction, and the connection structure penetrates through the second cap layer, the oxide layer, and the first cap layer vertically for contacting the top electrode.

3. The MRAM device according to claim 2, wherein a bottom surface of the first cap layer, a bottom surface of the oxide layer, and a bottom surface of the second cap layer are lower than a top surface of the top electrode in the vertical direction.

4. The MRAM device according to claim 2, wherein a top surface of the top electrode comprises a curved surface.

5. The MRAM device according to claim 1, wherein a sidewall of the oxide layer, a sidewall of the first cap layer, and a sidewall of the SOT layer are aligned with one another.

6. The MRAM device according to claim 1, wherein a bottom surface of the second cap layer is lower than a bottom surface of the first cap layer in the vertical direction.

7. The MRAM device according to claim 1, wherein the second cap layer is partly disposed on a sidewall of the first cap layer and a sidewall of the SOT layer.

8. The MRAM device according to claim 1, wherein a material composition of the oxide layer is different from a material composition of the first cap layer and a material composition of the second cap layer.

9. The MRAM device according to claim 1, wherein a material composition of the first cap layer is identical to a material composition of the second cap layer.

10. The MRAM device according to claim 1, wherein the oxide layer located above the MTJ structure is sandwiched between the first cap layer and the second cap layer in the vertical direction.

11. A manufacturing method of a magnetoresistive random access memory (MRAM) device, comprising:
forming a magnetic tunneling junction (MTJ) structure above a substrate;
forming a spin-orbit torque (SOT) layer above the substrate, wherein the MTJ structure is located on the SOT layer;
forming a first cap layer adjacent to the MTJ structure;
forming an oxide layer on the first cap layer;
forming a second cap layer on the oxide layer, wherein the first cap layer, the oxide layer, and the second cap layer are partly located above the MTJ structure in a vertical direction; and
forming a connection structure above the MTJ structure, wherein the connection structure penetrates through the second cap layer, the oxide layer, and the first cap layer vertically.

12. The manufacturing method of the MRAM device according to claim 11, wherein a method of forming the SOT layer comprises:
forming a SOT material above the substrate, wherein the MTJ structure is formed on the SOT material;
forming a cap material on the MTJ structure and the SOT material;
forming a patterned oxide material on the cap material; and
performing an etching process using the patterned oxide material as mask, wherein the SOT material is etched to be the SOT layer by the etching process, and a part of the patterned oxide material is located above the MTJ structure in the vertical direction after the etching process.

13. The manufacturing method of the MRAM device according to claim 12, wherein the substrate comprises a memory region and a logic region, the SOT material and the cap material are partly formed above the memory region and partly formed above the logic region, and the SOT material and the cap material located above the logic region are removed by the etching process.

14. The manufacturing method of the MRAM device according to claim 12, wherein the cap material is etched to be the first cap layer by the etching process, and the patterned oxide material is etched to be the oxide layer by the etching process.

15. The manufacturing method of the MRAM device according to claim 12, further comprising:
forming a top electrode above the substrate before the cap material is formed, wherein the top electrode is located above the MTJ structure, and the cap material covers the top electrode, the MTJ structure, and the SOT material.

16. The manufacturing method of the MRAM device according to claim 15, wherein the first cap layer, the oxide layer, and the second cap layer are partly located above the top electrode in the vertical direction, and the connection structure penetrates through the second cap layer, the oxide layer, and the first cap layer vertically for contacting the top electrode.

17. The manufacturing method of the MRAM device according to claim 15, wherein a bottom surface of the first cap layer, a bottom surface of the oxide layer, and a bottom surface of the second cap layer are lower than a top surface of the top electrode in the vertical direction.

18. The manufacturing method of the MRAM device according to claim 15, wherein a top surface of the top electrode comprises a curved surface.

19. The manufacturing method of the MRAM device according to claim 12, wherein the second cap layer is formed after the etching process, and the manufacturing method further comprises:
forming an interlayer dielectric layer on the second cap layer; and
performing a planarization process to the interlayer dielectric layer, wherein the planarization process stops on the second cap layer, and a bottom surface of the interlayer dielectric layer is lower than the MTJ structure in the vertical direction.

20. The manufacturing method of the MRAM device according to claim 19, wherein a dielectric constant of the interlayer dielectric layer is lower than a dielectric constant of the oxide layer.
